(19) United States
(12) Patent Application Publication
(10) Pub. No.: US 2026/0304664 A1
(43) Pub. Date: Oct. 1, 2026

(54) INTERFACE CONNECTION STRUCTURE

(71) Applicant: Coretronic Intelligent Robotics Corporation, Hsin-Chu (TW)

(72) Inventor: Min-Hsiu Wu, Hsin-Chu (TW)

(73) Assignee: Coretronic Intelligent Robotics Corporation, Hsin-Chu (TW)

(21) Appl. No.: 19/553,435

(22) Filed: Mar. 2, 2026

(30) Foreign Application Priority Data
Mar. 26, 2025 (TW) 114111348

(51) Int. Cl. H05K 5/06

(52) U.S. Cl. CPC H05K 5/069

(57) ABSTRACT

An electronic device including a housing, a thumb wheel, a sealing member and a sensor is provided. The thumb wheel is movably disposed in an accommodation space of the housing, and a portion of the thumb wheel is exposed from an operating opening of the housing. An active rod of the thumb wheel is located in the accommodation space. The sealing member is disposed in the accommodating space and is sealingly connected to the housing to form a first space, and the other portion of the thumb wheel is located in the first space. The linking member of the sealing member is fitted on the active rod. The sensor is disposed on a side of the sealing member away from the thumb wheel, and is connected to the linking member. The thumb wheel is adapted to rotate relative to the housing by a force to drive the sensor to rotate.

### CROSS-REFERENCE TO RELATED APPLICATION

The disclosure claims the priority benefit of Taiwan application serial no. 114111348, filed on Mar. 26, 2025. The entirety of the above-mentioned patent application is hereby incorporated by reference herein and made a part of this specification.

### BACKGROUND

### Technical Field

The disclosure relates to an electronic device.

### Description of Related Art

The modern electronic device may include a housing and a thumb wheel, and the thumb wheel is exposed from an opening of the housing. The user may operate the exposed thumb wheel to rotate, causing the electronic component inside the electronic device to generate a signal, and the electronic device may control the actuation of an external device through the signal. The impurities (for example, water) from the external environment may easily enter the housing through the opening of the housing and affect the electronic component inside the housing. Therefore, how to improve the waterproof performance inside the electronic device is a problem to be solved.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

The electronic device of the disclosure includes a housing, a thumb wheel, a sealing member, and a sensor. The housing has an accommodation space, and the housing includes an operating opening. The thumb wheel is movably disposed in the accommodation space, and a portion of the thumb wheel is exposed from the operating opening. The thumb wheel includes an active rod, and the active rod is located in the accommodation space. The sealing member is disposed in the accommodation space and is sealing connected to the housing to form a first space, the other portion of the thumb wheel is located in the first space. The sealing member includes a linking member, and the linking member is fitted on the active rod. The sensor is disposed on a side of the sealing member away from the thumb wheel, and the sensor is connected to an end of the linking member. The thumb wheel is adapted to rotate relative to the housing by a force, and the end of the linking member is adapted to be driven by the active rod to drive the sensor to rotate.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a schematic diagram of an electronic device according to an embodiment of the disclosure.

FIG. 2 is a simplified block diagram of the electronic device of FIG. 1.

FIG. 3 is a cross-sectional view of the electronic device of FIG. 1 along line A-A.

FIG. 4 is an exploded view of the electronic device of FIG. 3.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Unless limited otherwise, the terms “connected,” “coupled,” and “mounted,” and variations thereof herein are used broadly and encompass direct and indirect connections, couplings, and mountings. Accordingly, the drawings and descriptions will be regarded as illustrative in nature and not as restrictive.

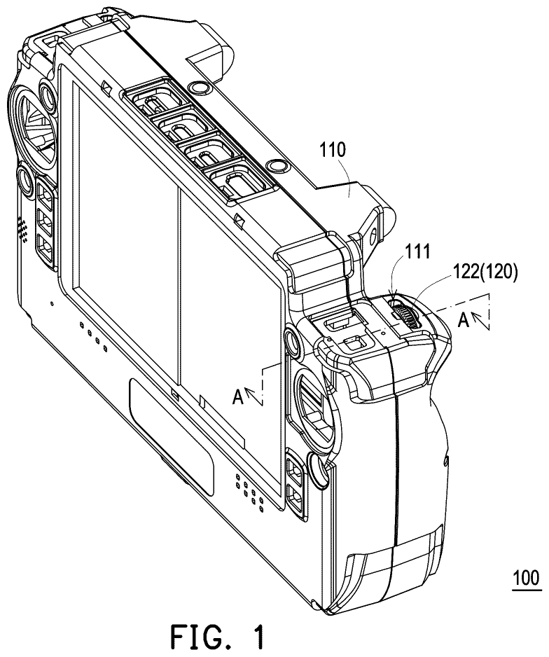

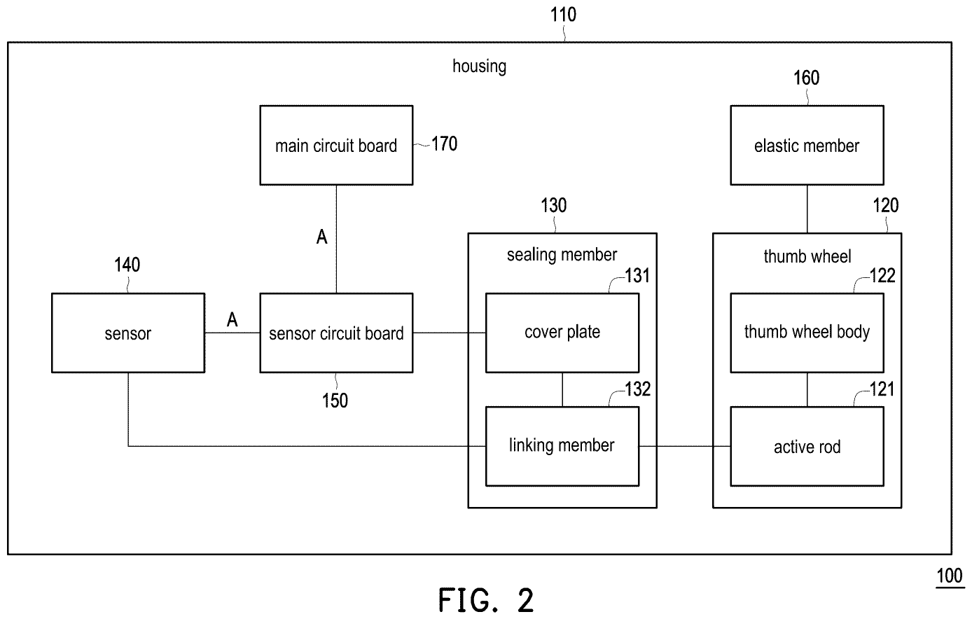

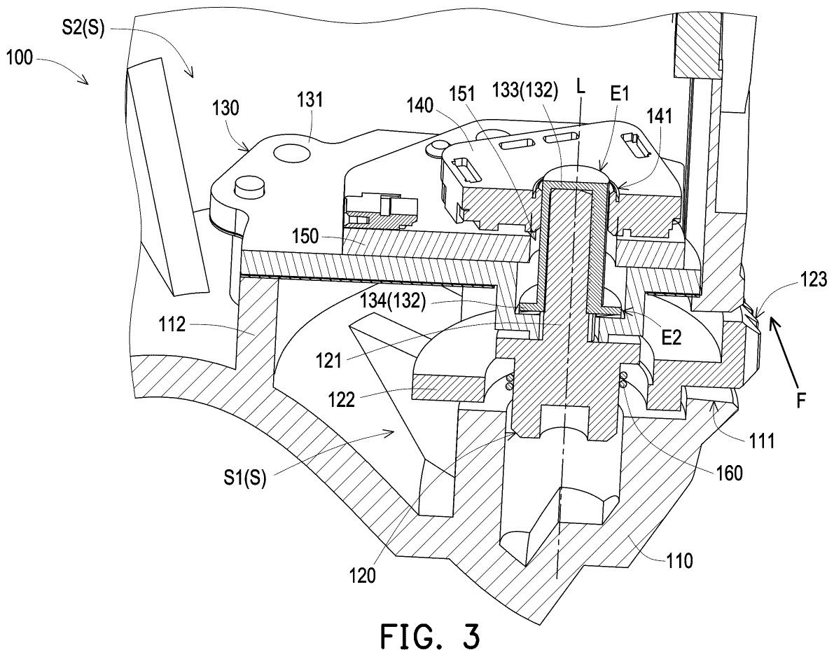

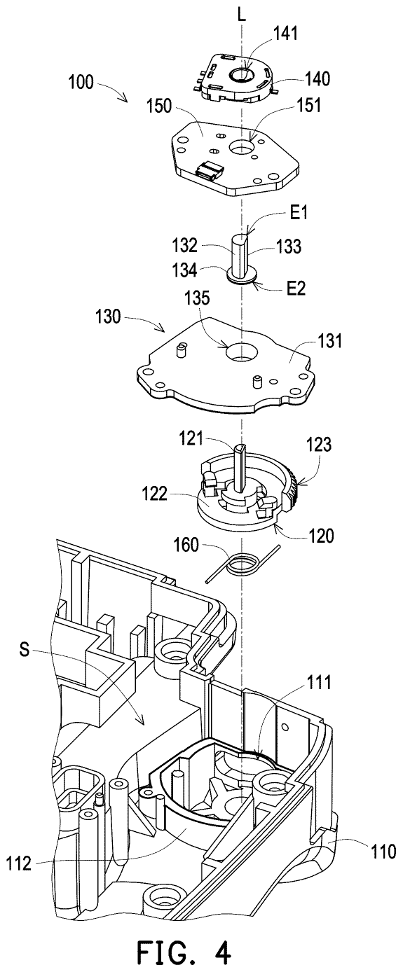

FIG. 1 is a schematic diagram of an electronic device according to an embodiment of the disclosure. FIG. 2 is a simplified block diagram of the electronic device of FIG. 1. FIG. 3 is a cross-sectional view of the electronic device of FIG. 1 along line A-A, showing the initial location of the components of the electronic device 100 when not acted upon by a force F. FIG. 4 is an exploded view of the electronic device of FIG. 3. Referring to FIG. 1 to FIG. 4 at the same time, the electronic device 100 includes a housing 110, a thumb wheel 120, a sealing member 130, and a sensor 140. The housing 110 has an accommodation space S and includes an operating opening 111. The thumb wheel 120 is movably disposed in the accommodation space S, a portion of the thumb wheel 120 is exposed from the operating opening 111. The thumb wheel 120 includes an active rod 121, and the active rod 121 is located in the accommodation space S. The sealing member 130 is disposed in the accommodation space S and is sealingly connected to the housing 110 to form a first space S1 in the accommodation space S, the other portion of the thumb wheel 120 is located in the first space S1.

The sealing member 130 includes a linking member 132, the linking member 132 is fitted on the active rod 121 along a connecting axis L, and the active rod 121 is located in the first space S1. The sensor 140 is disposed on a side of the sealing member 130 away from the thumb wheel 120, the sensor 140 is connected to an end E1 of the linking member 132, and is linked with the active rod 121. The thumb wheel 120 may rotate relative to the housing 110 by the force F, and the end E1 of the linking member 132 may be driven by the active rod 121 to drive the sensor 140 to rotate. Since the sealing member 130 is sealingly connected to the housing 110 and the portion of the thumb wheel 120 is exposed from the operating opening 111, the first space S1 communicates with the external environment through the operating opening 111, and is separated from other spaces of the accommodation space S via the sealing member 130. That is, the electronic components (for example, the sensor 140) inside the housing 110 of the electronic device 100 are located outside the first space S1 communicated with the external environment (i.e., located in other spaces within the accommodation space S of the housing 110).

When the impurities (for example, the dust and water) from the external environment enter the first space S1 through the operating opening 111, the impurities is blocked by the sealing member 130 within the first space S1, and not enter other spaces of the accommodation space S to affect the internal electronic components. The components located in the first space S1 (for example, the thumb wheel 120) have a simple structure and are not easily damaged, thereby reducing the impact of the impurities from the external environment on the electronic device 100. The electronic device 100 of this embodiment possesses a waterproof rating of IPX 5 or above, the electronic device 100 may effectively prevent water from entering other spaces of the accommodation space S through the first space S1 and affecting the internal electronic components. The electronic device 100 has better waterproof performance.

The electronic device 100 of this embodiment is, for example, a remote controller used for controlling an unmanned aerial vehicle gimbal, and the sensor 140 is, for example, a variable resistive sensor, but not limited thereto. The electronic device 100 may be applicable to other devices that need to prevent the impurities from entering from the external environment. When the thumb wheel 120 is driven to rotate the sensor 140 from the location in FIG. 3 (the initial location) relative to the housing 110, the sensor 140 generates a signal A including the rotation angle of the sensor, the signal A may be transmitted to a main circuit board 170 of the electronic device 100 and converted into a control signal to control the rotation of the unmanned aerial vehicle gimbal.

As shown in FIG. 2 and FIG. 3, the housing 110 includes an inner wall 112. The sealing member 130 is sealingly connected to the inner wall 112 to divide the accommodation space S into the first space S1 and a second space S2. The sensor 140, the main circuit board 170, and other electronic components (not shown) of the electronic device 100 are located in the second space S2. The sensor 140 includes a connecting opening 141, and the linking member 132 of the sealing member 130 and the active rod 121 of the thumb wheel 120 extend into the connecting opening 141 and engage with the sensor 140. The sealing member 130 and the inner wall 112 may be bonded through adhesive, but not limited thereto. The sealing member 130 and the housing 110 do not need to be sealed through an O-ring, allowing the manufacturing tolerance of the sealing member 130 to be larger, thereby improving the production yield of the electronic device 100 and reducing costs.

As shown in FIG. 3 and FIG. 4, the sealing member 130 further includes a cover plate 131. The other end E2 of the linking member 132 is connected to an opening 135 of the cover plate 131, and the active rod 121 is passed through the opening 135 of the cover plate 131. The material of the linking member 132 is a deformable soft material, including but not limited to a rubber or a silicone. The thumb wheel 120 may rotate relative to the housing 110 by the force F, and the end E1 of the linking member 132 connected to the sensor 140 may rotate relative to the end E2 of the linking member 132 connected to the cover plate 131. The linking member 132 may easily twist and deform relative to the cover plate 131 without affecting the feeling when the user operates the thumb wheel 120.

The linking member 132 of this embodiment includes a linking body 133 and a connecting portion 134. The connecting portion 134 is integral with the linking body 133 and extends in a direction perpendicular to the connecting axis L, the connecting portion 134 is sealingly connected to the cover plate 131 and is located within the opening 135 of the cover plate 131. The end E1 of the linking member 132 is an end of the linking body 133 away from the connecting portion 134, and the end E2 of the linking member 132 is an end of the connecting portion 134 connected to the cover plate 131. The active rod 121 of the thumb wheel 120 is a semi-circular cylinder extending along the connecting axis L, and the linking body 133 correspondingly is a semi-circular hollow cylinder, to fit over the active rod 121 and tightly adhere to the active rod 121. When the thumb wheel 120 rotates relative to the cover plate 131 from the initial location (shown in FIG. 3), the linking body 133 is driven by the active rod 121 to twist and deform relative to the connecting portion 134 with the connecting axis L as the center and accumulates an elastic force.

In this embodiment, the cover plate 131 and the linking member 132 are two separate portions, and the material of the cover plate 131 may be different from the material of the linking member 132, but not limited thereto. The cover plate 131 and the connecting portion 134 of the linking member 132 may be sealingly connected through any known method. For example, the cover plate 131 and the linking member 132 may be bonded through adhesive, but not limited thereto. In an embodiment not shown, the cover plate 131 and the linking member 132 may be integrally formed. The cover plate 131 and the linking member 132 may be manufactured using a two-stage injection molding process. This application does not impose limitations on the manufacturing and connecting methods of the cover plate 131 and the linking member 132.

As shown in FIG. 1, FIG. 3 and FIG. 4, the thumb wheel 120 includes a thumb wheel body 122, and the active rod 121 is connected to the thumb wheel body 122 along the connecting axis L. The thumb wheel body 122 is rotatably connected to the housing 110 along the connecting axis L. A portion of the thumb wheel body 122 is exposed from the operating opening 111. The exposed portion of the thumb wheel body 122 may have an anti-slip structure 123, to facilitate the user to push and rotate the thumb wheel 120. When the force F is applied to the thumb wheel body 122, the thumb wheel 120 rotates relative to the housing 110 with the connecting axis L as the rotation axis, causing the active rod 121 to drive the linking body 133 of the linking member 132 to twist.

The electronic device 100 further includes an elastic member 160 and a sensor circuit board 150. The elastic member 160 is located in the first space S1 (the accommodation space S) and connected to the thumb wheel 120, and the sensor circuit board 150 is located in the second space S2 and connected to the sealing member 130. The sensor 140 is rotatably connected to the sensor circuit board 150. The sensor circuit board 150 is located between the sensor 140 and the sealing member 130. The sensor circuit board 150 includes an opening 151, and the active rod 121 and the linking member 132 are passed through the opening 151. When the exposed portion of the thumb wheel 120 rotates relative to the housing 110 by the force F, the elastic member 160 deforms and accumulated an elastic force. When the force F is removed, the thumb wheel 120 returns to the original location through the elastic force of the elastic member 160 and the elastic force of the linking member 132, causing the sensor 140 to return to the initial location (shown in FIG. 3). In this embodiment, the elastic member 160 is a torsion spring, and the elastic member 160 is connected to the thumb wheel body 122 and the housing 110, but not limited thereto. In an embodiment not shown, the elastic member 160 may be connected only to the thumb wheel 120. The signal A generated by the sensor 140 is transmitted from the sensor 140 to the sensor circuit board 150, and is transmitted from the sensor circuit board 150 to the main circuit board 170 (shown in FIG. 2).

In summary, the sealing member of the electronic device of the disclosure seals with the housing to form a first space in the accommodation space of the housing, the thumb wheel is disposed in the first space that communicates with the external environment, and the sensor is located outside the first space (i.e., located in other spaces within the accommodation space of the housing). Thereby, when water from the external environment enters the first space through the operating opening of the housing, the water is blocked in the first space and not enter other spaces of the accommodation space to affect the internal electronic components, providing the interior of the electronic device with better waterproof performance.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The use of “at least one of . . . and . . . ” thereof herein may include “one or more of the items contained in the list”. For example, the use of “at least one of A and B” thereof herein may include only A, or only B, or A and B. Similarly, the use of “at least one of A, B, and C” thereof herein may include only A, or only B, or only C, or any combination of A, B, and C. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. An electronic device, comprising:
A housing, having an accommodation space, the housing comprises an operating opening;
A thumb wheel, movably disposed in the accommodation space, a portion of the thumb wheel is exposed from the operating opening, the thumb wheel comprises an active rod, and the active rod is located in the accommodation space;
A sealing member, disposed in the accommodation space and sealingly connected to the housing to form a first space, other portion of the thumb wheel is located in the first space, the sealing member comprises a linking member, and the linking member is fitted on the active rod; and
A sensor, disposed on a side of the sealing member away from the thumb wheel, the sensor is connected to an end of the linking member,
wherein the thumb wheel is adapted to rotate relative to the housing by a force, and the end of the linking member is adapted to be driven by the active rod to drive the sensor to rotate.

2. The electronic device according to claim 1, wherein the sealing member further comprises a cover plate, the other end of the linking member is connected to the cover plate, and the active rod is passed through the cover plate.

3. The electronic device according to claim 2, wherein the cover plate and the linking member are integrally formed.

4. The electronic device according to claim 2, wherein the thumb wheel is adapted to rotate relative to the housing by the force, and the end of the linking member connected to the sensor is adapted to rotate relative to the end of the linking member connected to the cover plate.

5. The electronic device according to claim 1, further comprises a sensor circuit board, the sensor is rotatably connected to the sensor circuit board, and the sensor circuit board is connected to the sealing member.

6. The electronic device according to claim 5, wherein the sensor circuit board comprises an opening, the active rod and the linking member are passed through the opening, and the sensor circuit board is located between the sensor and the sealing member.

7. The electronic device according to claim 1, wherein the thumb wheel comprises a thumb wheel body, the active rod is connected to the thumb wheel body, the thumb wheel body is rotatably connected to the housing, and a portion of the thumb wheel body is exposed from the operating opening.

8. The electronic device according to claim 1, further comprises an elastic member, the elastic member is located in the accommodation space, and the elastic member is connected to the thumb wheel, when the thumb wheel rotates relative to the housing by the force, the elastic member deforms and accumulates an elastic force.

9. The electronic device according to claim 1, wherein the housing comprises an inner wall, the sealing member is sealingly connected to the inner wall to divide the accommodation space into the first space and a second space, and the sensor is located in the second space.

10. The electronic device according to claim 1, wherein the material of the linking member comprises but not limited to a rubber or a silicone.
